(19) United States
(12) Patent Application Publication
(10) Pub. No.: US 2004/0259366 A1
(43) Pub. Date: Dec. 23, 2004

(54) Method and composition for the chemical-vibrational-mechanical planarization of copper

(76) Inventors: Seong Han Kim, State College, PA (US); Yongwu Zhao, State College, PA (US)

Correspondence Address: AIR PRODUCTS AND CHEMICALS, INC., PATENT DEPARTMENT, 7201 HAMILTON BOULEVARD, ALLENTOWN, PA, 181951501

(21) Appl. No.: 10/677,212

(22) Filed: Oct. 2, 2003

Related U.S. Application Data
(60) Provisional application No. 60/480,352, filed on Jun. 20, 2003.

(51) Int. Cl. H01L 21/302; H01L 21/461

(52) U.S. Cl. 438/691

(57) ABSTRACT

A mixture and method comprising same is described for chemical vibrational mechanical polishing (CVMP) of excess material from the underlying substrate surface. In one embodiment of the present invention, the method comprises: providing the substrate comprising the copper layer and the excess copper-containing material disposed thereupon; introducing the substrate into a vessel containing a chemical mechanical polishing mixture comprising a solution and a plurality of particles wherein the solution comprises an etchant, a modifier, and a surfactant and wherein an average particle diameter of the particles ranges from 100 to 3000 μm; and agitating the vessel with the substrate contained therein to remove the excess copper-containing material from the substrate.

### CROSS-REFERENCE TO RELATED APPLICATIONS

This application claims the benefit of U.S. Provisional Application No. 60/480,352, filed Jun. 20, 2003, the disclosure of which is incorporated by reference herein in its entirety.

### BACKGROUND OF THE INVENTION

This invention generally relates to a method and composition for the chemical mechanical polish (CMP) of semiconductor substrates upon which a copper layer is deposited thereupon. More specifically, the present invention relates to a method and a composition for the chemical-vibrational-mechanical planarization (CVMP) of a copper layer on a substrate surface.

In the semiconductor industry, copper interconnects are increasingly being used as an interconnect material rather than aluminum. The superior electrical conductivity of copper over aluminum may result in higher speed interconnections of greater current carrying capability. Currently, copper interconnects are formed using a so-called “damascene” or “dual-damascene” fabrication process. Briefly, a damascene metallization process forms interconnects by the deposition of conducting metals in recesses formed on a semiconductor wafer surface. Typically, semiconductor devices (e.g., integrated circuits) are formed on a semiconductor substrate. These substrates are generally covered with an oxide layer. Material may be removed from selected regions of the oxide layer creating openings referred to as in-laid regions within the substrate surface. These in-laid regions correspond to a circuit interconnect pattern forming the conductor wiring of the device.

Once the in-laid pattern has been formed within the oxide layer, a thin barrier layer may be fabricated that evenly blankets the patterned oxide layer. This barrier layer may composed of, but is not limited to, titanium nitride, tantalum nitride, or tungsten nitride. After the barrier layer is formed, a seed layer of a conductive metal, preferably comprising copper, is deposited. The seed layer of copper forms the foundation for the bulk deposition of copper by a variety of deposition techniques including, but not limited to, physical sputtering, chemical vapor deposition (CVD), or electroplating. After the bulk copper has been deposited, excess copper may be removed using, for example, by chemical-mechanical polishing (CMP). Besides removing excess material, the CMP process adds in achieving planarity of the substrate surface. CMP of copper layers are particularly challenging due to the fact that the copper, the underlying substrate material, and the diffusion barrier material are removed at different rates. This problem is often referred to as “selectivity”. Other problems associated with CMP processes, particularly copper layers, include: copper dishing, oxide erosion, and field loss.

In CMP processes, polishing and removal of excess material is accomplished through a combination of chemical and mechanical means. In a typical CMP process, a wafer surface may be mechanically scrubbed via a polishing pad while a chemically reactive slurry containing abrasive particles flows over the surface. In yet another CMP process referred to as “fixed abrasive CMP”, abrasive particles may be embedded within the surface of the polishing pad while the surface of the wafer is contacted with chemically reactive slurry.

The prior art discloses a variety of reactive slurries or solutions suitable for CMP polishing of copper layers. U.S. Pat. No. 5,354,490 discloses an aqueous-based CMP polishing slurry comprising HNO₃, H₂SO₄, AgNO₃, or mixtures thereof and a solid abrasive material. U.S. Pat. No. 5,780,358 discloses a non-aqueous, CMP slurry that contains a solvent, halogen radical producing specie, and abrasive particles. U.S. Pat. No. 5,863,838 discloses a CMP method for polishing a metal layer such as aluminum, copper, and tungsten by applying a mixture comprising an organic salt, which decomposes into an oxidizer and a surfactant. U.S. Pat. No. 5,897,375 describes a slurry for CMP polishing that contains an oxidizing species such as H₂O₂, a carboxylate salt, an optional triazole or triazole derivative, an abrasive material such as alumina and/or silica particles, and a solvent such as deionized water. U.S. Pat. No. 6,096,652 describes a CMP slurry containing water, an oxidizing agent, an abrasive component, a first coordinating ligand that forms a complex with Cu (I) such as a triazole, and a second coordinating ligand that forms a complex with Cu (II) such as an amine or carboxylate. U.S. Pat. No. 6,276,996 discloses two different reactive slurries for “fixed abrasive CMP” that are void of solid abrasive material depending upon the pH of the slurry. In the '996 patent, the slurry contains a copper oxidizing component and either a copper corrosion inhibitor or a copper complexing agent depending upon the pH of the slurry.

Some prior art methods try to address the selectivity issue by employing a two-step process. U.S. Pat. No. 6,001,730 describes a two-step CMP method involving a first slurry, containing an oxidizing species such as H₂O₂, a carboxylate salt, an optional triazole or triazole derivative, and an abrasive material such as alumina and/or silica particles and a hard polishing pad, for removing the bulk copper layer and a second slurry, containing a solvent such as an alcohol or deionized water, a silica abrasive, and an amine compound, and a soft polishing pad for polishing the tantalum-based barrier layer. U.S. Pat. No. 6,083,840 discloses a two-step process for CMP polishing of copper layers that employs two different slurries for bulk copper polishing and copper/diffusion barrier layer/substrate polishing, respectively. In the '840 patent, the first slurry comprises water, an abrasive having a mean particle diameter ranging from 10 to 800 nanometers (nm), a carboxylic acid, and an oxidizer and the second slurry comprises water, an abrasive having a mean particle diameter ranging from 10 to 800 nm, an acid, and an oxidizer.

Despite the foregoing, there remains a need to develop a CMP process and/or slurry to improve the CMP polishing of a substrate. These is a need for a high-throughput process to improve the CMP polishing of a substrate and avoid potential damage into contact holes and lines of the underlying substrate.

All references cited herein are incorporated herein by reference in their entireties.

### BRIEF SUMMARY OF THE INVENTION

The present invention satisfies one, if not all, of the needs in the art by providing a method for the removal of an excess copper-containing material from a substrate comprising: providing the substrate comprising the copper layer and the excess copper-containing material disposed thereupon; introducing the substrate into a vessel containing a chemical mechanical polishing mixture comprising a solution and a plurality of particles wherein the solution comprises an etchant, a modifier, and a surfactant and wherein an average particle diameter of the particles ranges from 100 to 3000 μm; and agitating the vessel with the substrate contained therein to remove the excess copper-containing material from the substrate.

In a further aspect of the invention, there is provided a method for the removal of an excess material from the surface of a substrate comprising: introducing the substrate into a vessel having a chemical mechanical polishing mixture comprising a chemical solution and a plurality of particles having an average particle diameter ranging from 100 to 3000 μm; and agitating the vessel with the substrate and the chemical mechanical polishing mixture contained therein to remove the excess material from the substrate.

In yet another aspect of the invention, there is provided a method for the removal of an excess copper-containing material from a substrate comprising a copper layer comprising: providing a chemical mechanical polishing mixture comprising a solution comprising an etchant, a modifier, and a surfactant and a plurality of non-abrasive particles wherein the average particle diameter ranges from 100 to 3000 μm and wherein a solution to void volume ratio of the solution to the particles is about 1 or less; and contacting the substrate with the mixture to remove the excess copper-containing material from the substrate.

In a still further aspect of the invention, there is provided a chemical mechanical polishing mixture comprising: a solution comprising an etchant, a modifier, and a surfactant; and a plurality of particles having an average particle diameter ranging from 100 to about 3000 μm.

In another aspect of the invention, there is provided a chemical mechanical polishing mixture comprising: a solution comprising from about 0.1% to 20% by weight of an etchant, 0.1% to 15% by weight of a modifier, 0.001% to 10% by weight of a surfactant, and 50 to 99% of a solvent; and a plurality of particles with an average particle diameter ranging from 100 to 3000 μm, wherein a solution to void volume ratio of the solution to the particles is about one or less.

These and other aspects of the present invention will be more apparent from the following description.

### BRIEF DESCRIPTION OF SEVERAL VIEWS OF THE DRAWINGS

FIG. 1 provides an illustration of one embodiment of the CVMP method of the present invention.

FIG. 2 provides a comparison of the 3 different chemical solutions under static, quasi-static, and CVMP conditions.

FIG. 3 shows the copper removal rate via CVMP for a 1.5 μm, electroplated Cu film.

FIG. 4 provides the results of a X-ray photoelectron analysis of a Cu/Ti/Si wafer after complete removal of the Cu film via CVMP treatment

FIG. 5 provides the topography (top of the figure) and conductance (bottom of the figure) AFM images of the a patterned silicon wafer having a copper layer deposited thereupon after 6 minutes of CVMP treatment.

FIGS. 6a through 6b provide atomic force microscope (AFM) images of the surface of a silicon dioxide film after treatment with water, CVMP treatment with a chemical mechanical polishing mixture, and treatment with non-abrasive particles, respectively.

### DETAILED DESCRIPTION OF THE INVENTION

The present invention provides a chemical mechanical polishing mixture and a chemical-vibrational-mechanical planarization (CVMP) method comprising same that effectively removes excess metal material, preferably a copper or a copper-containing material, from an underlying substrate without causing process defects such as dishing or scratches on the underlying dielectric layer. In contrast to prior art CMP processes, the method of the present invention does not necessarily rely upon polishing pads for the removal of the excess material. Instead, the present invention removes the excess material through the interaction of the chemical mechanical polishing mixture with the excess material and gentle, frequent collisions with relatively larger, preferably non-abrasive, particles. Since the mechanical abrasive action is greatly reduced compared to prior art processes, the CVMP process of the present invention may be self-limiting, i.e., may automatically end the removal process at the dielectric layer. In this regard, the CVMP method may prevent over-polishing thereby eliminating the need for a polish stop layer or real-time end-point detection. Further, the particles, due to their larger size relative to the diameter of the contact holes and line widths, generally avoids affecting the surface of the metal or copper in contact holes and lines thereby preventing dishing problems.

As mentioned previously, the chemical mechanical polishing mixture and CVMP method may be used to remove excess metal material, such as copper, copper-containing metals, aluminum, or combinations thereof, from the surface of a substrate. In certain preferred embodiments, the excess metal material to be removed comprises a copper or a copper-containing material. The terms “copper” and “copper-containing materials” are used interchangeably herein and includes, but is not limited to, substrates comprising layers of pure copper, copper-containing alloys such as Cu—Al alloys, and Ti/TiN/Cu, and Ta/TaN/Cu multi-layer substrates. Suitable substrates that may be used in the present invention include, but are not limited to, semiconductor materials such as gallium arsenide (“GaAs”), boronitride (“BN”) silicon, and compositions containing silicon such as crystalline silicon, polysilicon, amorphous silicon, epitaxial silicon, silicon dioxide (“SiO₂”), silicon carbide (“SiC”), silicon oxycarbide (“SiOC”), silicon nitride (“SiN”), silicon carbonitride (“SiCN”), organosilica glasses (“OSG”), organofluorosilicate glasses (“OFSG”), fluorosilicate glasses (“FSG”), and other appropriate substrates or mixtures thereof. Substrates may further comprise a variety of layers to which the metal material such as copper is applied thereto such as, for example, diffusion barrier layers (e.g., TiN, Ti(C)N, TaN, Ta(C)N, Ta, W, WN, TiSiN, TaSiN, SiCN, TiSiCN, TaSiCN, or W(C)N), antireflective coatings, photoresists, organic polymers, porous organic, inorganic materials, and additional metal layers.

The CVMP method of the present invention employs a chemical mechanical polishing mixture comprising a chemical solution component and a mechanical component, or a plurality of particles, in conjunction with agitation to remove excess material from the underlying substrate. The solution within the mixture comprises at least one etchant, at least one modifier, and at least one surfactant. The solution to void volume ratio, or the ratio of solution volume to the void volume of the particles within the mixture, is about 1 or less, preferably about 0.2 or less. The average particle size diameter of the non-abrasive particles within the mixture ranges from about 100 to about 3000 microns (μm), preferably from 500 to 1000 μm, and more preferably from 1000 to 2000 μm. The pH of the mixture may range from 1 to 7, preferably from 1 to 4. The pH of the solution may be adjusted to the desired range using any known acid, base, or amine. However, it is preferable that any acid and/or base used contain substantially no metal ions to avoid introducing undesirable metal components to the solution. Examples of suitable acid or bases include ammonium hydroxide and amines, or nitric, phosphoric, sulfuric, or organic acids.

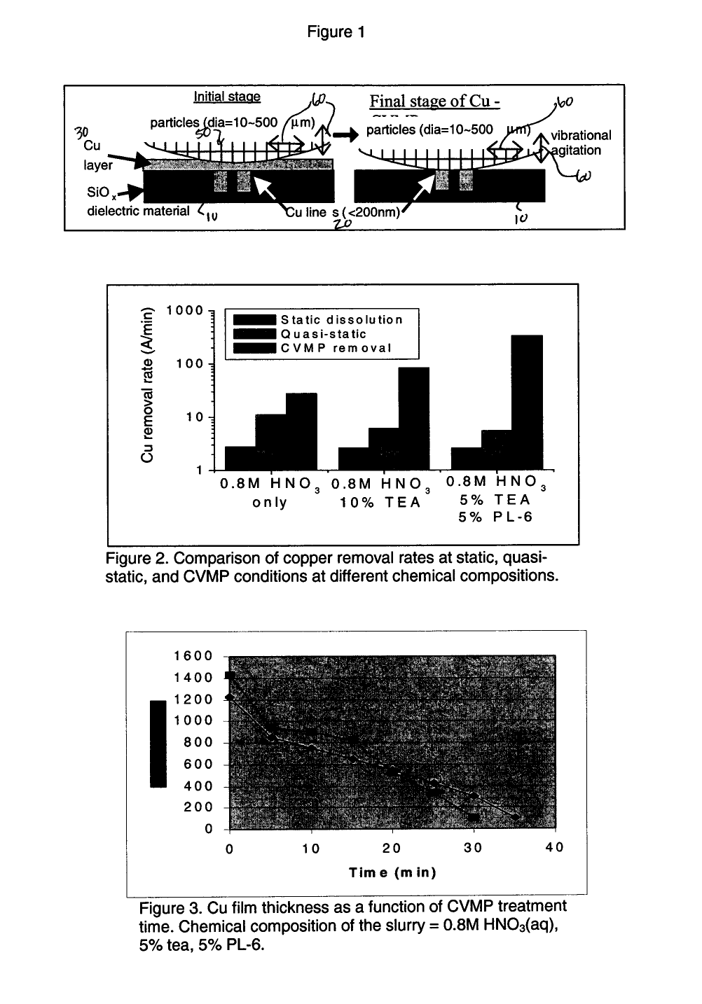

FIG. 1 provides an illustration of one embodiment of the present invention. Referring to FIG. 1, substrate 10, comprised of a SiOx dielectric material, contains copper lines 20 which have a line width less than 200 nanometers (nm) and a layer of excess copper material 30. Substrate 10 is contacted with a chemical mechanical polishing mixture 40 containing non-abrasive particles 50 (shown as grid-lines) having an average particle size diameter ranging from 100 to about 3000 μm suspended in a solution (not shown). Arrows 60 illustrate the vibrational agitation of the particles, which makes, frequent, mild impacts upon the surface of substrate 10. As FIG. 1 illustrates, this vibrational agitation of the particles upon the substrate causes the removal of excess copper material 30 (see final stage).

The chemical mechanical polishing mixture comprises a chemical solution and a plurality of particles. The chemical solution comprises at least one etchant, at least one modifier, and at least one surfactant. The selection and amount of etchant and modifier within the solution depends upon a variety of factors such as the excess material to be removed, the removal rate desired, frequency or amplitude of agitation, etc.

As mentioned previously, the solution of the present invention comprises at least one etchant. The term “etchant” as used herein describes a reagent that is reactive to the excess material to be removed. The one or more etchants that is added to the solution preferably will not form precipitates at the desired pH range of the solution. Examples of suitable etchants for the removal of copper or copper-containing materials include peroxides (e.g., hydrogen peroxide (H₂O₂), urea-hydrogen peroxide, or urea peroxide); inorganic acids or salts thereof (e.g., nitric acid (HNO₃), iodic acid, periodic acid, periodate salts, perbromic acid, perbromate salts, perchloric acid, perchloric salts, perboric acid, perborate salts); nitrates (e.g., ferric nitrate (Fe(NO₃)₃), silver nitrate (AgNO₃), ammonium cerium nitrate), halogen-containing compounds (e.g., chlorates, perchlorates, chlorites, ferric chloride, iodates, bromates); sulphates; persulphates; oxidizers (e.g., ozone); and combinations thereof. In certain preferred embodiments of the present invention, the etchant is an inorganic acid such as nitric acid. The weight percent of etchant within the solution ranges from about 0. 1% to about 20%, preferably from about 1% to about 10%, and more preferably about 1% to about 5% by weight.

The solution of the present invention comprises at least one modifier. The term “modifier” as used herein describes a reagent that effects the performance of the etchant within the solution, i.e., may enhance or may inhibit the action of the etchant under processing conditions. Examples of suitable modifiers include organic acids (e.g., citric acid); amines (e.g., triethanolamine (TEA)); nitrogen-containing cyclic compounds such as imidazole, benzotriazole (BTA), benzimidizole and benzotriazole and their derivatives having hydroxy, amino, imino, carboxy, mercapto, nitro, urea, thiourea, and alkyl substituted groups; and combinations thereof. In certain preferred embodiments, the modifier is an amine compound such as triethanolamine. The weight percent of modifier within the solution ranges from about 0.1% to about 15%, preferably from about 0.1% to about 10%, and more preferably from about 0.1% to about 5% by weight.

The solution of the present invention further includes at least one surfactant. The surfactant can be anionic, cationic, nonionic, or amphoteric. Further classifications of surfactant include silicone surfactants, poly(alkylene oxide) surfactants, and fluorochemical surfactants. Suitable surfactants for use in the solution include, but are not limited to, octyl and nonyl phenol ethoxylates such as TRITON® X-114, X-102, X-45, X-15; alcohol ethoxylates such as BRIJ® 56 (C₁₆H₃₃(OCH₂CH₂)₁₀OH) (ICI), BRIJ® 58 (C₁₆H₃₃(OCH₂CH₂)₂₀OH) (ICI), and acetylenic diols such as SURFYNOLS® 465 and 485 (Air Products and Chemicals, Inc.). Further surfactants include polymeric compounds such as the tri-block EO-PO-EO co-polymers PLURONIC® L121, L123, L31, L81, L101 and P123 (BASF, Inc.). Still further exemplary surfactants include alcohol (primary and secondary) ethoxylates such as an ethoxylated phosphate esters, amine ethoxylates, glucosides, glucamides, polyethylene glycols, poly(ethylene glycol-co-propylene glycol), or other surfactants provided in the reference McCutcheon's Emulsifiers and Detergents, North American Edition for the Year 2000 published by Manufacturers Confectioners Publishing Co. of Glen Rock, N.J. In preferred embodiments, the surfactant is an ethoxylated phosphate ester. The weight percent of surfactant within the solution ranges from about 0.001% to about 10%, preferably from about 0.1% to about 7%, and more preferably from about 0.1% to about 5% by weight.

The balance of the solution preferably comprises a solvent. Examples of suitable solvents used within the solution may include, but are not limited to, deionized water, distilled water, hydrocarbons (e. g. pentane or hexane); halocarbons (e. g. Freon 113); ethers (e. g. ethylether (Et₂O) or tetrahydrofuran (“THF”)); nitriles (e. g. CH₃CN); aromatic compounds (e.g. benzotrifluoride), alcohols (e.g., 3-heptanol, 2-methyl-1 -pentanol, 5-methyl-2-hexanol, 3-hexanol), or combinations thereof. In certain preferred embodiments, the solvent is deionized water.

The solution of the present invention may further comprise a variety of optional additives to, for example, adjust the pH of the solution, prevent settling, flocculation, or decomposition of the resultant chemical mechanical polishing mixture, such as, but not limited to, stabilizers, thickeners, buffers, or dispersants. The amount of these additional additives may range from about 0.001% to about 5%, preferably from about 0.001% to about 3%, and more preferably from about 0.1% to about 1% by weight.

In addition to the chemical solution, the chemical mechanical mixture further includes a plurality of particles. The term “particle” as used herein refers to both aggregates of more than one primary particle and to individual single particles. The average particle size diameter of the particles within the mixture ranges from about 100 to about 3000 μm, preferably from 500 to 2000 μm, and more preferably from 1000 to 2000 μm. In certain preferred embodiments, the particles have a relatively narrow size distribution, such as, for example, 1000 to 2000 μm. The particles are preferably comprised of a ceramic material such as, but not limited to, aluminum oxide such as alpha- and/or gamma-alumina or fumed alumina, fused silica, silicon carbide, titanium oxide, magnesium oxide, zirconium oxide, porcelain, cerium oxide, or combinations thereof. However, other materials having sufficient hardness (i.e., have hardness greater than the material to be removed) and are substantially chemically inert to the solution within the chemical mechanical polishing mixture may also be used. In certain preferred embodiments, the particles are comprised of alumina. The particles can be comprised of a variety of shapes including random shapes, cones, spheres, cylinders, ellipses, triangles, stars, etc. The shapes of the particles are preferably substantially round such as substantially cylindrical, spherical, or elliptical, or have a minimal amount of sharp edges. The surface of the particles are preferably smooth or non-abrasive to minimize scratches on the underlying dielectric layer and/or dishing of the Cu layer.

The chemical mechanical polishing mixture may be prepared using conventional techniques. Typically, the chemical solution is prepared first by adding the solution ingredients, such as the at least one etchant, at least one modifier, surfactant, and any optional additives, into a solvent medium, preferably an aqueous solvent such as deionized or distilled water, at predetermined concentrations under low shear conditions until the solution components are substantially dissolved in the solvent medium. Then, the particles are added to the solution until the desired solution to void volume ratio is reached. As mentioned previously, it is preferred that the particles be aged or exposed to the chemical solution for at least 8 hours, preferably at least 12 hours, or more preferably at least 24 hours, prior to contacting the chemical mechanical polishing mixture with the substrate.

In an alternative embodiment of the invention, a concentrated composition is provided that may be diluted in water and/or other solvents to provide the chemical solution component of the chemical mechanical polishing mixture of the present invention. A concentrated composition of the invention, or “concentrate” allows one to dilute the concentrate to the desired strength and pH. A concentrate also permits longer shelf life and easier shipping and storage of the product. After the chemical solution concentrate is diluted to the desired strength and pH, the particles can be added to achieve the desired solution to void volume ratio to form the chemical mechanical polishing mixture.

A variety of means can be employed in contacting the chemical mechanical polishing mixture solution with the substrate surface. The actual conditions of the contacting step (i.e., temperature, time, and the like) may vary over wide ranges and are generally dependent on a variety of factors such as, but not limited to, the nature and amount of material to be removed on the surface of the substrate, the removal rate of the material by the chemical solution, the topography of the substrate, etc.

In certain preferred embodiments of the present invention, the contacting step is conducted through a CVMP process. In these embodiments, the substrate having excess material to be removed is contacted with the chemical mechanical polishing mixture without the need for conventional polishing pads and/or polishing machines used in typical CMP processes. In the CVMP process, one or more substrates is contacted within the chemical mechanical polishing mixture which is then agitated to remove the excess material. Preferably, the substrate(s) is introduced into a vessel containing the mixture and the mixture is then agitated with respect to the substrate(s). The substrate(s) is preferably in a fixed position relative to the motion of the mixture and/or the vessel. The agitation may be conducted a variety of means such as, but not limited to, vibratory motion (e.g., electromechanical or mechanical), ultrasonic motion, pulsatory motion, sonic motion, acoustic motion, centrifugal motion, and combinations thereof. The amplitude, frequency, direction, and duration of these motions may vary depending upon numerous factors such as the capacity of the vessel, the material to be removed, the removal rate of the chemical solution, etc. For example, the duration of the agitation step may range from 30 seconds to 120 minutes, preferably from 1 minute to 60 minutes, and more preferably from 1 minute to 40 minutes.

In certain preferred embodiments, the agitation is conducted via a vibratory motion such as electromechanical vibration. In these embodiments, the frequency of the vibratory motion may range from 20 to 200 Hz, preferably from 60 to 120 Hz. The amplitude of the vibratory motion may range from 0.1 to 5 mm, preferably from 0.1 to 3 mm.

The chemical mechanical polishing mixture and method comprising same of the present invention may be used at various stages of semiconductor integrated circuit manufacture to provide effective polishing at desirable polishing rates while minimizing surface imperfections and defects. While it is preferred that the mixture and the method of the present invention be used in conjunction with each other, it is anticipated that the mixture and the method may be useful independently. In this regard, the mixture of the present invention may be useful in a conventional CMP process or, alternatively, known slurries in the art may be suitable when used in the CVMP process of the present invention.

The invention will be illustrated in more detail with reference to the following Examples, but it should be understood that the present invention is not deemed to be limited thereto.

### EXAMPLES

For the following examples, two bench-top, mechanical vibratory bowls manufactured by C&M Topline of Yalesville, Conn. were employed. The vibratory bowl model no. TLV 75 was equipped with a 0.75 cubic foot (CF) polymer bowl and an 110v@60 Hz drive. The vibratory bowl model no. TLV 25 was equipped with a 0.25 CF polymer bowl but the drive was modified to have variable frequency from 10 to 100 Hz. Atomic force microscope (AFM) and X-ray photoelectron spectroscopy (XPS), was used to analyze the surface topography and chemistry of some of the examples. The AFM images were taken using a microscope head attached to a molecular imager with RHK Electronics. The XPS analysis was conducted using a VG MKII ESCA system.

Unless otherwise stated, the particles used in the chemical mechanical polishing mixture were alumina particles having a rounded cylindrical shape and an average particle diameter ranging from about 2 to about 3 millimeters (mm) and were provided by Vibrodyne Co. of Dayton, Ohio. Unless otherwise stated, all of the samples used herein where 1 cm×1 cm silicon dioxide wafers provided by Wafernet, Inc. of San, Jose, Calif. having a 300 Å TaN diffusion barrier layer, a 1,500 Å Cu layer applied via plasma vapor deposition, and a 15,000 Å Cu layer applied via electroplating (or a total of 1.65 micron thickness of Cu coating). All experimentation was conducted at room temperature.

### Example 1

### Comparison of Copper Removal Rates at Static, Quasi-Static and CVMP Conditions for Different Chemical Solutions

Three different chemical solutions were prepared and compared under various conditions. Each solution was mixed until the ingredients were dissolved within the solution. Solution 1 was comprised of 0.8M HNO₃ (etchant) and the balance deionized water. Solution 2 was comprised of 0.8M HNO₃ (etchant), 10% triethanolamine (TEA) (modifier), and the balance deionized water. Solution 3 was comprised of 0.8M HNO₃ (etchant), 5% TEA (modifier), 5% of the ethoxylated phosphate ester surfactant, Rhodafac™ PL-6 provided by Rhodia USA of Cranbury, N.J., and the balance deionized water.

The three chemical solutions were tested on the 1cm×cm silicon wafers, having TaN and copper layers deposited thereupon, under the following conditions. The results of each test are provided in Table I and FIG. 2.

In the static dissolution test, the wafer was immersed in each chemical solution until the Cu layer was removed. An overall dissolution rate was calculated based on the Cu layer thickness and the time taken to remove the layer.

In the quasi-static test, a small amount of each chemical solution was added into ceramic particles contained in a beaker and mixed thoroughly to form a mixture. The particles, which was manufactured by Vibrodyne Company of Dayton, Ohio, were comprised of alumina having a random shape and an average particle diameter of about 1 mm and a nominal density of 2.3 g/cm³. The solution to particle void volume ratio was 0.2. The wafer was placed into the beaker and the mixture was stirred gently. An overall dissolution rate was calculated based on the Cu layer thickness and the time taken to remove this layer.

In the CVMP test, each chemical solution was added into the TLV 25 vibratory container, which also contained alumina particles. The particles, which were manufactured by Vibrodyne Company of Dayton, Ohio, were comprised of alumina having a random shape and an average particle diameter of about 1 mm and a nominal density of 2.3 g/cm³. The solution to particle void volume ratio was 0.2. The wafer was glued at the end of a shaft and immersed into the mixture containing each chemical solution and the particles. In this regard, the motion of the wafer was effectively separated from the motion of the media, enhancing the mechanical action. The container having the wafer, chemical solution, and particles container therein, was agitated at a frequency of 60 Hz until the Cu layer on the wafer was completely removed. The time duration for the removal of the Cu layer was then recorded.

Referring to Table I and FIG. 2, chemical solution 3 exhibited the fastest Cu removal rate under CVMP conditions. Solution 2 had a faster CVMP removal rate compared to solution 1 whereas the static dissolution rate was substantially the same and the quasi-static dissolution rate increased. Solution 3 also had substantially the same static dissolution rate and an increased quasi-static dissolution rate. However, solution 3 had a substantially decreased Cu removal rate in the CVMP condition, i.e., factor or 3˜4. The removal rate difference between the CVMP and static conditions was increased two orders of magnitude when 5% of the PL-6 surfactant was added to the mixture.

TABLE I
Time for complete removal of 50 nm Cu layer

| | | | 5% TEA |
|---|---|---|---|
| Solution | | 10% TEA | 5% PL-6 |
| composition | 0.8 M HNO₃ | 0.8 M HNO₃ | 0.8 M HNO₃ |
| Static dissolution | 180˜190 min | 180˜190 min | 180˜192 min |
| test | | | |
| Quasi-static | 45˜50 min | 60˜82 min | 70˜91 min |
| dissolution test | | | |
| (1 mm media, | | | |
| solution | | | |
| volume/particle void | | | |
| volume = 0.2) | | | |
| CVMP test (1 mm | 17˜19 min | 5.5˜6.5 min | 1.25˜2 min |
| media, solution | | | |
| volume/particle void | | | |
| volume 0.2, 60 Hz | | | |
| vibration frequency) | | | |

### Example 2

### CVMP of Copper Layer Using Mixture Containing 2-3 mm Cylindrical Shaped Alumina Media and Solution of HNO₃ (0.8M), TEA (5%), and PL-6 (5%)

An aqueous chemical solution was prepared using HNO₃ (0.8M), TEA (5%), and PL-6 (5%) in accordance with the method described in Example 1. The chemical mechanical polishing mixture was prepared by adding cylindrically shaped aluminum oxide particles, ranging in size from approximately 2 to approximately 3 mm and manufactured by Vibrodyne Inc. of Dayton, Ohio, until the solution to particle void volume ratio of 0.2 was reached. The media was allowed to age overnight in the solution prior to use.

The mixture was added into the bowl of the TLV25 vibratory container. A CVMP test was conducted in accordance with the method described in Example 1. The CVMP conditions were as follows: the chemical solution was comprised of 0.8M HNO3, 5% TEA, 5% PL-6; the particles were alumina beads having an average particle diameter of approximately 2 mm; the solution to particle void volume ratio was 0.2; and the agitation was conducted via vibratory motion for a duration of 6 minutes at a frequency of 60 Hz on the TLV25 machine.

FIG. 3 compares the copper removal rate via CVMP for two silicon wafers having the TaN and copper layers deposited thereupon. FIG. 3 illustrates that the results of the CVMP process is reproducible from one sample to the other.

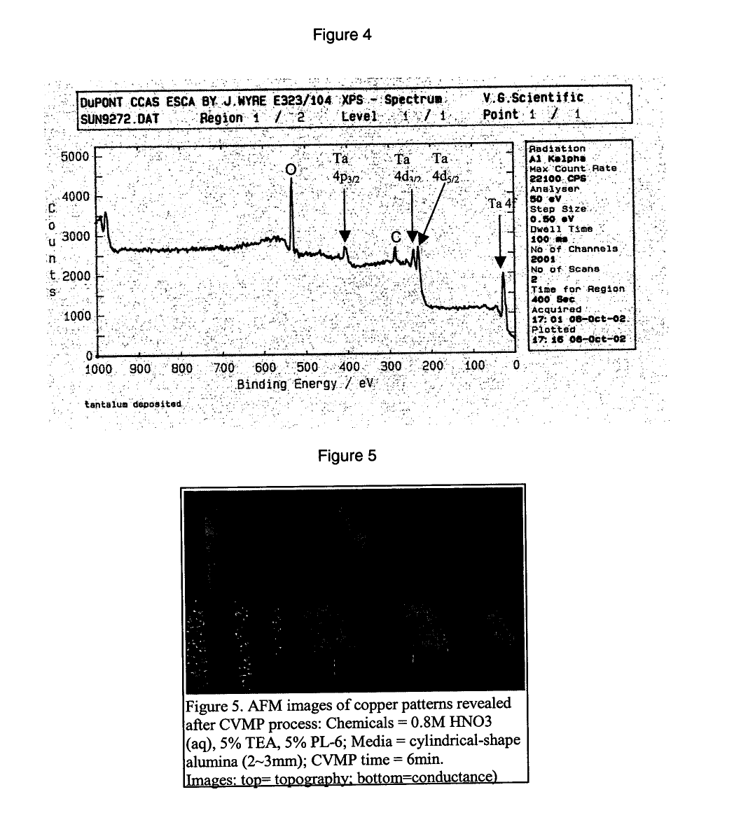

FIG. 4 provides the X-ray photoelectron analysis of the wafer having the TaN and copper layers deposited thereupon after 6 minutes of CVMP treatment. The analysis confirms the absence of the Cu layer and the remainder of the thick tantalum barrier layer on the silicon wafer.

### Example 3

### CVMP Performed on a Patterned Wafer

A patterned silicon wafer having a TaN and copper layer deposited thereupon was provided by DuPont AirProducts NanoMaterials LLC. The feature sizes of the wafer ranged from approximately 1 to approximately 10 μm. The patterned silicon wafer was subjected to CVMP treatment as described in Example 1 except for the following: the chemical mechanical polishing mixture had a chemical solution (0.8M HNO₃, 5% TEA, 5% PL-6 and the balance deionized water); a plurality of 2-3 mm, cylindrically shaped alumina particles; and ratio of solution to void volume of the particles of 0.2. The wafer was in a fixed position and placed in the TLV 25 vibratory bowl and agitated for 6 minutes at a vibration frequency of 60 HZ and a vibration amplitude ranging from approximately 2 to 3 mm.

FIG. 5 provides AFM images (topography and conductance) of the wafer having the TaN and copper layers deposited thereupon after 6 minutes of CVMP treatment. The flat region is dielectric surface and the lower region with granular feature is copper. The high conductance of the topographically lower surface confirms that they are copper surfaces. Based on the two orders of magnitude difference between the dynamic and static removal rates observed in Example 1, it is believed that the copper surface in lithographically patterned trenches (width <200 nm) would not be effectively removed by the CVMP process because the large particles with macroscopic curvatures cannot penetrate into the copper surface in the trenches more than a few Angstroms from the dielectric surface. Example 1 shows that the copper overlayer was completely removed via CVMP in less than 10 minutes. However, the copper removal in the trenches appeared to be much faster than the expected rate, producing about 213±52 nm dishing into the patterned copper trenches after 6 minutes of CVMP treatment. This indicates that the copper in the lithographically patterned trenches may be removed much faster than copper in the continuous thin film over the dielectric layer. The fast etching rate of copper in the patterned trenches may be due to subsurface defects generated during the trench filling via copper deposition.

### Example 4

### Comparison of Substrate Surface Finish under Variety of Process Conditions

Three substrates having a silicon dioxide film deposited upon its surface were loaded into the TLV 25 vibratory bowl. The vibratory bowl further contained cylindrically shaped alumina particles (manufactured by Vibrodyne Co. of Dayton, Ohio) having an average diameter ranging from 2 to 3 mm.

Each substrate was subjected to the following process conditions: Substrate 1, or the control, was cleaned with water and not subjected to the CVMP process. Substrate 2 was processed via the CVMP process and exposed to the chemical solution, containing 0.8M HNO₃, 5% TEA, 5% PL-6 and the balance deionized water, and the alumina particles to provide a mixture. The ratio of solution to void volume of the mixture was 0.2. Substrate 2 was then agitated within the mixture for 10 minutes at a frequency of 30 Hz and an amplitude of 3 mm. Substrate 3 was placed in the TLV 25 vibratory bowl with the alumina particles only and agitated for 10 minutes at a frequency of 30 Hz and an amplitude of 3 mm. No water or chemical solution was added to the vibratory bowl containing substrate 3.

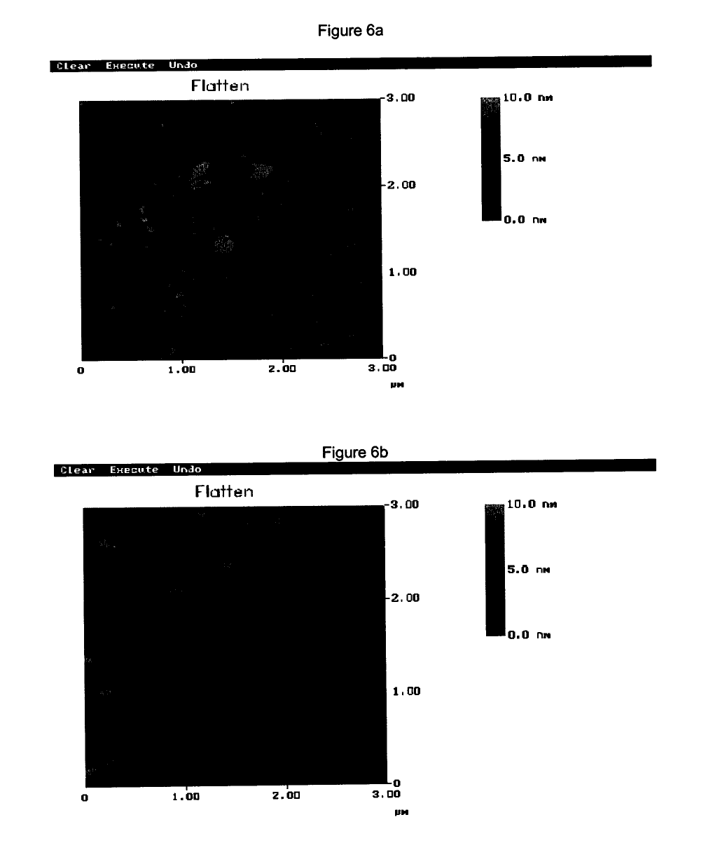

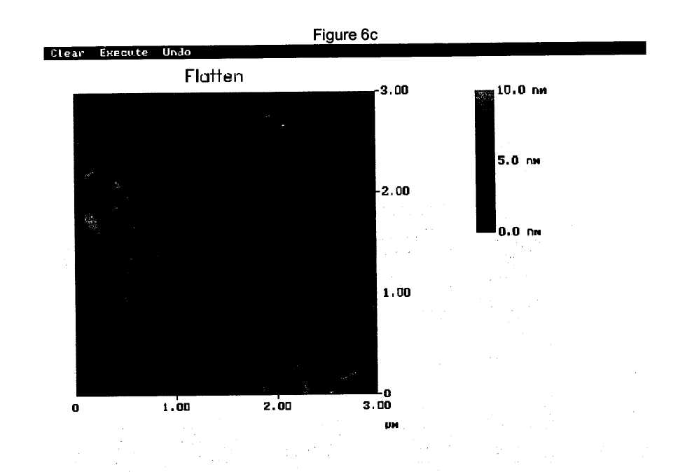

The silicon dioxide films of substrates 1 through 3 were then examined via AFM and the results are provided in FIGS. 6a through 6c, respectively. The height of the full scale of these figures equals 10 nm. FIGS. 6b and 6c illustrate that treatment with the alumina particles, either with or without the chemical solution, did not make any scratches on the substrate surface. Further, the quality of the CVMP-treated surface in FIG. 6b equaled or surpassed the quality of surfaces treated via conventional CMP processes. The few trenches observed in FIGS. 6b and 6c were only approximately 2 nanometers (nm) deep. It is believed that these trenches may be caused by the sharp edges of the particles within the mixture.

While the invention has been described in detail and with reference to specific examples thereof, it will be apparent to one skilled in the art that various changes and modifications can be made therein without departing from the spirit and scope thereof.

1. A method for the removal of an excess copper-containing material from a substrate comprising a copper layer, the process comprising:
providing the substrate comprising the copper layer and the excess copper-containing material disposed thereupon;
introducing the substrate into a vessel containing a chemical mechanical polishing mixture comprising a solution and a plurality of particles wherein the solution comprises an etchant, a modifier, and a surfactant and wherein an average particle diameter of the particles ranges from 100 to 3000 μm; and
agitating the vessel with the substrate contained therein to remove the excess copper-containing material from the substrate.

2. The method of claim 1 wherein a solution to void volume ratio is one or less.

3. The method of claim 2 wherein the solution to void volume ratio is 0.2 or less.

4. The method of claim 1 wherein the solution is contacted with the plurality of particles for at least 8 hours prior to the introducing step.

5. The method of claim 1 wherein the agitating step is conducted by at least one member selected from the group consisting of vibratory motion, ultrasonic motion, pulsatory motion, sonic motion, acoustic motion, centrifugal motion, and combinations thereof.

6. The method of claim 1 wherein the agitating step is conducted by vibratory motion.

7. The method of claim 6 wherein the frequency of the vibratory motion ranges from 20 to 200 Hz.

8. The method of claim 6 wherein the amplitude of the vibratory motion ranges from 0.1 to 5 mm.

9. A method for the removal of an excess material from the surface of a substrate, the method comprising:
introducing the substrate into a vessel having a chemical mechanical polishing mixture comprising a chemical solution and a plurality of particles having an average particle diameter ranging from 100 to 3000 μm; and
agitating the vessel with the substrate and the chemical mechanical polishing mixture contained therein to remove the excess material from the substrate.

10. A method for the removal of an excess copper-containing material from a substrate comprising a copper layer, the process comprising:
providing a chemical mechanical polishing mixture comprising a solution comprising an etchant, a modifier, and a surfactant and a plurality of non-abrasive particles wherein the average particle diameter ranges from 100 to 3000 μm and wherein a solution to void volume ratio is about 1 or less; and
contacting the substrate with the mixture to remove the excess copper-containing material from the substrate.

11. The method of claim 10 wherein the contacting step comprises:
introducing the substrate into a vessel containing the chemical mechanical polishing mixture; and
agitating the vessel with the substrate and the chemical mechanical polishing mixture contained therein to remove the excess copper-containing material from the substrate.

12. The method of claim 10 wherein the solution is contacted with the plurality of particles for at least 8 hours prior to the contacting step.

13. A chemical mechanical polishing mixture, the mixture comprising:
a solution comprising an etchant, a modifier, and a surfactant; and
a plurality of particles having an average particle diameter ranging from 100 to about 3000 μm.

14. The mixture of claim 13 wherein a solution to void volume ratio is about one or less.

15. The mixture of claim 13 wherein the solution further comprises a solvent.

16. The mixture of claim 13 wherein the plurality of particles is contacted with the solution for a duration of at least 8 hours.

17. The mixture of claim 13 wherein the etchant is at least one member selected from the group consisting of peroxides; inorganic acids or salts thereof; nitrates, halogen-containing compounds; sulphates; persulphates; and combinations thereof.

18. The mixture of claim 13 wherein the modifier is at least one member selected from the group consisting of organic acids; amines; nitrogen-containing cyclic compounds; and combinations thereof.

19. A chemical mechanical polishing mixture, the mixture comprising:
a solution comprising from about 0.1% to 20% by weight of an etchant, 0.1% to 15% by weight of a modifier, and 0.001% to 10% by weight of a surfactant, and 50 to 99% of a solvent; and
a plurality of particles with an average particle diameter ranging from 100 to 3000 μm,
wherein a solution to void volume ratio is about one or less.

20. The mixture of claim 19 wherein the solution is contacted with the plurality of particles for at least 8 hours.

21. The mixture of claim 19 wherein the particles comprise non-abrasive particles.

22. The mixture of claim 19 wherein the particles are comprised of at least one member selected from the group consisting of aluminum oxide, silicon dioxide, silicon carbide, titanium oxide, magnesium oxide, zirconium oxide, porcelain, cerium oxide, and combinations thereof.
